(19) United States
(12) Patent Application Publication
(10) Pub. No.: US 2025/0192586 A1
(43) Pub. Date: Jun. 12, 2025

(54) CHARGING AND DISCHARGING TEST DEVICE

(71) Applicant: EV Motors Japan Co., Ltd., Kitakyushu-shi, Fukuoka (JP)

(72) Inventor: Yuji Sato, Kitakyushu-shi, Fukuoka (JP)

(73) Assignee: EV Motors Japan Co., Ltd., Kitakyushu-shi, Fukuoka (JP)

(21) Appl. No.: 18/845,243

(22) PCT Filed: Mar. 10, 2022
(86) PCT No.: PCT/JP2022/010680

§ 371 Date: Sep. 9, 2024

(51) Int. Cl. H02J 7/00; H02J 7/35

(52) U.S. Cl. CPC H02J 7/005; H02J 7/0013; H02J 7/007182; H02J 7/35; H02J 2207/20

(57) ABSTRACT

A charging and discharging test device comprises an AC/DC converter having an AC-side terminal connected to a commercial AC power supply and a DC-side terminal connected to a common DC bus, a plurality of bidirectional DC/DC converters each having one end connected to the common DC bus and another end connected to each test object in which a plurality of secondary batteries are connected in series, a storage battery and an auxiliary power generation means connected to the common DC bus, and a control unit which controls each bidirectional DC/DC converter. At the time of charging and discharging of each test object, transmission and reception of power are performed between each test object and the storage battery, and a shortage in power of the storage battery is supplemented with power generated by the auxiliary power generation means.

### TECHNICAL FIELD

The present invention relates to a charging and discharging test device which can collectively and efficiently conduct charging and discharging tests (service life tests) of many secondary batteries such as lithium-ion batteries with little consumed power.

### BACKGROUND ART

In recent years, the demand for secondary batteries (mainly, lithium-ion batteries) has been rapidly increasing due to the development of IT devices such as smartphones and practical realization of electric vehicles and the like. In the final process of the course of mass production of such secondary batteries, activation and quality inspections of the produced secondary batteries are conducted, and shipments are made after an inspection by a charging and discharging test as to whether predetermined performance and characteristics are satisfied. However, in accordance with popularization of electric vehicles and the like, capacity of secondary batteries is increased, and a power consumption amount in the charging and discharging test is becoming large. In addition, since many secondary batteries are used in electric vehicles and the like, a charging and discharging device that can test a greater number of secondary batteries concurrently and efficiently while saving power is required. Thus, for example, Patent Document 1 proposes a charging and discharging test system comprising a bidirectional AC/DC converter having an AC-side terminal connected to an AC power supply and a DC-side terminal connected to a DC bus, a bidirectional DC/DC converter having one end connected to the DC bus and another end connected to a sample (secondary battery), and a control device which controls the bidirectional DC/DC converter to control charging and discharging against the sample by the bidirectional DC/DC converter. The number of the bidirectional DC/DC converters connected to the DC bus is larger than the number of the bidirectional AC/DC converters connected to the DC bus. The control device controls a plurality of the bidirectional DC/DC converters in accordance with charging and discharging patterns of a plurality of samples each connected to the plurality of bidirectional DC/DC converters, and the charging and discharging patterns of the plurality of samples are scheduled such that regenerative power supplied from the plurality of bidirectional DC/DC converters to the bidirectional AC/DC converter is minimized.

### CITATION LIST

### Patent Literature

Patent Document 1: Japanese Unexamined Patent Application Publication No. 2012-154793

### SUMMARY OF INVENTION

### Technical Problem

In Patent Document 1, by providing the DC bus for exchanging currents among the plurality of bidirectional DC/DC converters, regenerative power that is returned from the bidirectional AC/DC converter to the AC bus is reduced, and an AC conversion loss in the bidirectional AC/DC converter is reduced, thereby improving power usage efficiency of the charging and discharging test system. However, there is a need to supply power from grid power (commercial AC power supply) and charge a plurality of secondary batteries to be the targets of testing every time new secondary batteries are to be tested, and it is difficult to reduce the power consumption amount itself. Cost reduction has limitations, and it may also become difficult to secure power. In addition, in the control device, when controlling the plurality of bidirectional DC/DC converters in accordance with the charging and discharging patterns of the plurality of samples each connected to the plurality of bidirectional DC/DC converters, scheduling must be made such that regenerative power supplied from the plurality of bidirectional DC/DC converters to the bidirectional AC/DC converter is minimized, and this requires complicated control, which may lead to an increase in the cost. It should be noted that Patent Document 1 describes that, by additionally connecting a storage battery to the DC bus, peak power of the AC regenerative power supply (bidirectional AC/DC converter) is lowered, and contribution is made to scale reduction and cost reduction of the AC regenerative power supply, but there is no specific description as to how the storage battery is used, and operations thereof are unclear.

The present invention has been made in consideration of such circumstance, and an object thereof is to provide a charging and discharging test device which can perform an evaluation on service life at a low cost without complicated control while significantly reducing consumed power, by repeatedly reusing energy given at an early stage and performing charging and discharging of a plurality of secondary batteries.

### Solution to Problem

A charging and discharging test device according to the present invention complying with the object is a charging and discharging test device for simultaneously conducting charging and discharging tests of a plurality of test objects, each of the test objects being a plurality of secondary batteries connected in series, the charging and discharging test device comprising: an AC/DC converter having an AC-side (alternating current side) terminal connected to a commercial AC power supply and a DC-side (direct current side) terminal connected to a common DC bus; a plurality of bidirectional DC/DC converters each having one end connected to the common DC bus and another end connected to each of the test objects; a storage battery connected to the common DC bus; an auxiliary power generation means connected to the common DC bus; and a control unit which controls each of the bidirectional DC/DC converters, wherein at the time of charging and discharging of each of the test objects, transmission and reception of power are performed between each of the test objects and the storage battery, and a shortage in power of the storage battery is supplemented with power generated by the auxiliary power generation means.

In the charging and discharging test device according to the present invention, each of the test objects may be a battery module in which the plurality of secondary batteries are connected in series and modularized, or an assembled battery in which a plurality of battery modules, each being identical to the battery module, are connected in series.

In the charging and discharging test device according to the present invention, the AC/DC converter is preferably a bidirectional AC/DC converter.

In the charging and discharging test device according to the present invention, the auxiliary power generation means is preferably a solar panel.

The charging and discharging test device according to the present invention can comprise a voltage adjusting means which is, during the charging and discharging tests, connected to each of the test objects, and controlled with the control unit to perform adjustment such that a charging and discharging voltage of each of the secondary batteries falls within a preset allowable variation range.

### Advantageous Effects of Invention

The charging and discharging test device according to the present invention is capable of repeatedly performing charging and discharging between the test objects (a plurality of secondary batteries connected in series) and the storage battery. Since power supply from the commercial AC power supply is unnecessary after the storage battery is charged at an early stage, consumed power can be significantly reduced, and service life tests of a plurality of the test objects (many secondary batteries) can be simultaneously conducted with extremely little energy. Instead of converting DC regenerative power (discharge energy) at the time of discharging of the test object into AC regenerative power and returning this to the commercial AC power supply, the DC regenerative power can be stored on the storage battery as it is, and reused at the time of charging of the test object. In this manner, a conversion loss of regenerative power can be eliminated, and the regenerative power can be effectively used with high efficiency. Since discharge energy of the test object is stored on the storage battery and reused as charge energy, peak power is reduced, and power can be stably and certainly supplied during the tests. It is possible to continuously supply power at a constant voltage from the storage battery with no interruption without performing control on power outage, and stability of operations is excellent. Since a shortage in power of the storage battery is supplemented with power generated by the auxiliary power generation means, the usage or the electrical bill of the commercial AC power supply can be reduced as much as possible, and cost reduction can be achieved.

In the charging and discharging test device according to the present invention, if the test object is a battery module in which a plurality of secondary batteries are connected in series and modularized, or an assembled battery in which a plurality of the battery modules are connected in series, the charging and discharging tests of one or a plurality of the battery modules or the assembled batteries can be conducted also as the charging and discharging test of each secondary battery. There is no need to separately conduct the charging and discharging test of each secondary battery and the charging and discharging test of the battery module or the assembled battery, and thus effort and time for the charging and discharging test can be significantly reduced as compared to conventional ones.

In the charging and discharging test device according to the present invention, if the AC/DC converter is a bidirectional AC/DC converter, at the time when the storage battery is in a fully charged state and DC regenerative power (discharge energy) of the test object cannot be consumed as charge energy, surplus DC regenerative power can be converted into AC regenerative power and returned to the commercial AC power supply.

In the charging and discharging test device according to the present invention, if the auxiliary power generation means is a solar panel, a shortage in power can be supplemented with solar power generation, and emission of carbon dioxide can be reduced.

If the charging and discharging test device according to the present invention comprises a voltage adjusting means which is, during the charging and discharging tests, connected to each of the test objects, and controlled with the control unit to perform adjustment such that a charging and discharging voltage of each of the secondary batteries falls within a preset allowable variation range, it becomes possible to decrease an influence of a variation in characteristics (battery internal resistance values and the like) of a plurality of secondary batteries connected in series, and end the charging and discharging tests of all the secondary batteries at the same timing. Thus, it is excellent in efficiency, and occurrence of being overcharged, uncharged, undischarged, and the like can be prevented, resulting in realization of safe and accurate tests and excellent reliability of service life determination.

### BRIEF DESCRIPTION OF DRAWING

FIG. 1 is an explanatory diagram showing a configuration of a charging and discharging test device according to an embodiment of the present invention.

### DESCRIPTION OF EMBODIMENTS

Subsequently, with reference to the accompanying drawing, descriptions will be given of embodiments embodying the present invention for a better understanding of the present invention.

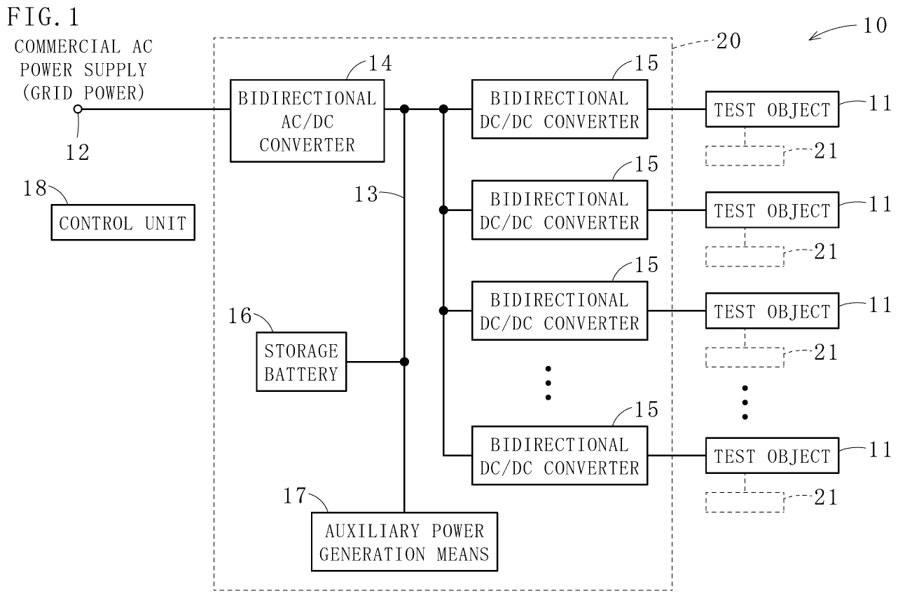

A charging and discharging test device 10 according to an embodiment of the present invention illustrated in FIG. 1 is for simultaneously conducting charging and discharging tests of a plurality of test objects 11, each of the test objects 11 being a plurality of secondary batteries connected in series. This charging and discharging test device 10 is also used for activation and quality inspections of produced secondary batteries (for example, lithium-ion batteries), but in particular, is preferably used for a service life test (prediction of battery service life).

Hereinafter, details of the charging and discharging test device 10 will be described.

As illustrated in FIG. 1, the charging and discharging test device 10 comprises a bidirectional AC/DC converter (an example of an AC/DC converter) 14 having an AC-side terminal connected to a commercial AC power supply 12 and a DC-side terminal connected to a common DC bus 13, and a plurality of bidirectional DC/DC converters 15 each having one end connected to the common DC bus 13 and another end connected to the test object 11 in which a plurality of secondary batteries are connected in series. In addition, the charging and discharging test device 10 comprises a storage battery 16 connected to the common DC bus 13, an auxiliary power generation means 17 connected to the common DC bus 13, and a control unit 18 which controls each bidirectional DC/DC converter 15. This charging and discharging test device 10 controls charging and discharging against each test object 11 (each secondary battery) by controlling each bidirectional DC/DC converter 15 with the control unit 18. Charging and discharging of each test object 11 are performed by transmission and reception of power between each test object 11 and the storage battery 16, but if there is a shortage in power of the storage battery 16, supplement is made with power generated by the auxiliary power generation means 17.

In this regard, the bidirectional AC/DC converter 14, the bidirectional DC/DC converters 15, the storage battery 16, and the auxiliary power generation means 17 constitute a power supply unit 20.

With the configuration as above, the charging and discharging tests can be repeatedly conducted while minimizing power supply from the commercial AC power supply 12, and it becomes possible to perform an evaluation on service life also for a test object (secondary battery) of large capacity, for which realization of such evaluation of service life has been conventionally difficult. Accordingly, by conducting the charging and discharging test with a new secondary battery to be used for an electric vehicle or the like being set as the test object, and saving results thereof (a charging curve and/or a discharging curve), service life of a second-hand secondary battery can be predicted by a comparison with a result of the charging and discharging test conducted with a second-hand secondary battery of the same type being set as the test object. In this manner, it is possible to judge whether to sell (use) the second-hand secondary battery or decide a reasonable price of purchase and sale, and expansion and optimization of a second-hand market of secondary batteries (electric vehicles) can be promoted.

In the charging and discharging test device 10, due to the change from a conventional AC bus to the common DC bus 13, there is no need to connect a bidirectional AC/DC converter to each bidirectional DC/DC converter 15, and the configuration is simplified. It should be noted that although at least one AC/DC converter is needed to supply power from the commercial AC power supply 12 to the common DC bus 13, by using the bidirectional AC/DC converter 14, at the time when the storage battery 16 is in a fully charged state and DC regenerative power (discharge energy) of the test object 11 (each secondary battery) cannot be consumed also as charge energy, surplus DC regenerative power can be converted into AC regenerative power and returned to the commercial AC power supply 12. In addition, since the test object 11 and the storage battery 16 are each connected to the common DC bus 13, DC regenerative power (discharge energy) when the test object 11 discharges can be stored on the storage battery 16 and reused at the time of charging of the test object 11 without being converted into AC regenerative power. Accordingly, a conversion loss of regenerative power can be eliminated, and the regenerative power can be used with a high efficiency, thereby allowing conduct of the charging and discharging test of the test object 11 certainly and continuously without an influence of power outage.

In addition, if there is a shortage in power of the storage battery 16, since supplement can be made with power generated by the auxiliary power generation means 17, the charging and discharging test device 10 can reduce the usage or the electrical bill of the commercial AC power supply 12 and cost reduction can be achieved. At this time, the auxiliary power generation means 17 may be of one type, or a plurality of types may be combined for use. It should be noted that, instead of the auxiliary power generation means 17, power can be stored on the storage battery 16 by midnight power, or the auxiliary power generation means 17 and the midnight power may be combined and the two may be used for different purposes in accordance with weathers and periods of time. However, power can also be stored on the storage battery 16 with the commercial AC power supply 12 as needed.

The auxiliary power generation means 17 is preferably a solar panel (solar power generation) but is not limited to this, and it may use renewable energy of wind power generation, etc.

Next, operations of the charging and discharging test device 10 will be described.

Firstly, a plurality of secondary batteries as the test object 11 are serially connected to each bidirectional DC/DC converter 15. The test object 11 (each secondary battery) of an early stage is in an uncharged state, and the storage battery 16 is charged beforehand with the commercial AC power supply 12 (or power generated by the auxiliary power generation means 17). Once charging to each test object 11 is instructed by the control unit 18, power is supplied from the storage battery 16 to each test object 11, and the charging to each test object 11 (each secondary battery) is performed. Once discharging from each test object 11 is instructed by the control unit 18 after the end of the charging process, power is supplied from each test object 11 to the storage battery 16, and the discharging from each test object 11 (each secondary battery) is performed. In this manner, charging and discharging of each test object 11 are repeated by transmission and reception of power between each test object 11 and the storage battery 16, but charging times and discharging times of each test object 11 differ from one another depending on a difference in characteristics (performance) (for example, variations and the like of internal resistance, capacity, and the like). Accordingly, each test object 11 is in an asynchronous state, and it individually repeats charging and discharging with the storage battery 16. The test object 11 that repeated charging and discharging for a predetermined number of times and completed the charging and discharging test is sent to the next process according to an instruction from the control unit 18, and the test of the test object 11 newly conveyed is conducted as needed. Since a shortage in power of the storage battery 16 is supplemented with power generated by the auxiliary power generation means 17, the charging and discharging test can be continuously carried on. The storage battery 16 is preferably a lithium-ion battery, and its capacity can be appropriately selected in accordance with the total capacity of the test objects 11 simultaneously tested. That is to say, the number of the test objects 11 or the number of secondary batteries constituting each test object 11 can be selected such that the total capacity of the test objects 11 simultaneously tested falls within the range of the capacity of the storage battery 16, and secondary batteries of different capacity and types can also be simultaneously tested.

It should be noted that any test object may be used as long as it is a test object in which a plurality of secondary batteries are connected in series, and it may be a battery module in which a plurality of secondary batteries are connected in series and modularized, or may be an assembled battery in which a plurality of the battery modules are connected in series.

In this regard, the charging and discharging test device 10 can comprise a voltage adjusting means 21 which is, during the charging and discharging tests, connected to each test object 11, and controlled with the control unit 18 to perform adjustment such that a charging and discharging voltage of each secondary battery constituting each test object 11 falls within a preset allowable variation range.

The voltage adjusting means 21 includes, for example, a means having a voltage measuring circuit which measures a charging and discharging voltage of each secondary battery with a voltage sensor electrically connected in parallel to each secondary battery constituting each test object 11, and a bypass circuit with an on-off switch which is connected in parallel to each secondary battery. By controlling each voltage sensor and each bypass circuit (on-off switch) with the control unit 18, during the charging and discharging tests, a charging and discharging voltage of each secondary battery is measured at a preset measurement time interval, and the bypass circuit that is connected in parallel to a secondary battery in which the measured charging and discharging voltage is higher than a reference voltage level is turned on for a given length of time such that a part of charging and discharging currents of the corresponding secondary battery is distributed to the bypass circuit. As a result, the charging and discharging currents flowing in the secondary battery in which the charging and discharging voltage is higher than the reference voltage level are decreased, and charging and discharging are suppressed, thereby resulting in a decrease of a variation in the charging and discharging voltage as a whole. At this time, the currents distributed to the bypass circuit are discharged with a resistor serially connected to the on-off switch and consumed as heat energy.

The embodiments of the present invention have been described above, but the present invention is not at all limited to the configurations described in the above embodiments, and other embodiments and modifications that can be considered within the scope of matters described in the claims are also included.

The secondary battery to be the test object includes nickel hydrogen batteries, nickel-cadmium batteries, lead storage batteries, and the like, besides lithium-ion batteries.

In the above-described embodiments, the bidirectional AC/DC converter is connected between the commercial AC power supply and the common DC bus, but it does not always have to be a bidirectional AC/DC converter. In addition, the number of the bidirectional DC/DC converters to be connected to the common DC bus is selected as appropriate.

### INDUSTRIAL APPLICABILITY

According to the charging and discharging test device of the present invention, energy given at an early stage is repeatedly reused to perform charging and discharging of a plurality of secondary batteries, and an evaluation on service life can be performed at a low cost without complicated control while significantly reducing consumed power. In particular, contribution can be made to expansion and optimization of a second-hand market of electric vehicles (large capacity secondary batteries).

### REFERENCE SIGNS LIST

10: charging and discharging test device, 11: test object, 12: commercial AC power supply, 13: common DC bus, 14: bidirectional AC/DC converter, 15: bidirectional DC/DC converter, 16: storage battery, 17: auxiliary power generation means, 18: control unit, 20: power supply unit, 21: voltage adjusting means

1. A charging and discharging test device for simultaneously conducting charging and discharging tests of a plurality of test objects, each of the test objects being a plurality of secondary batteries connected in series, the charging and discharging test device comprising:
an AC/DC converter having an AC-side terminal connected to a commercial AC power supply and a DC-side terminal connected to a common DC bus;
a plurality of bidirectional DC/DC converters each having one end connected to the common DC bus and another end connected to each of the test objects;
a storage battery connected to the common DC bus;
an auxiliary power generation means connected to the common DC bus; and
a control unit which controls each of the bidirectional DC/DC converters, wherein
at the time of charging and discharging of each of the test objects, transmission and reception of power are performed between each of the test objects and the storage battery, and a shortage in power of the storage battery is supplemented with power generated by the auxiliary power generation means.

2. The charging and discharging test device according to claim 1, wherein each of the test objects is a battery module in which the plurality of secondary batteries is connected in series and modularized, or an assembled battery in which a plurality of battery modules, each being identical to the battery module, is connected in series.

3. The charging and discharging test device according to claim 1, wherein the AC/DC converter is a bidirectional AC/DC converter.

4. The charging and discharging test device according to claim 1, wherein the auxiliary power generation means is a solar panel.

5. The charging and discharging test device according to claim 1, wherein the charging and discharging test device comprises a voltage adjusting means which is, during the charging and discharging tests, connected to each of the test objects, and controlled with the control unit to perform adjustment such that a charging and discharging voltage of each of the secondary batteries falls within a preset allowable variation range.
